(19) United States
(12) Patent Application Publication
(10) Pub. No.: US 2026/0128687 A1
(43) Pub. Date: May 7, 2026

(54) Harnessing Vibrational Energy in Fan Trays

(71) Applicant: Cisco Technology, Inc., San Jose, CA (US)

(72) Inventors: Carolina Hau Loo, SAN JOSE, CA (US); Bhumil Rajnikant Depani, San Jose, CA (US); Joel Richard Goergen, Soulsbyville, CA (US); Marc Mantelli, Los Gatos, CA (US)

(21) Appl. No.: 18/939,963

(22) Filed: Nov. 7, 2024

(51) Int. Cl. H02N 2/18; H05K 7/20; H10N 30/50

(52) U.S. Cl. CPC H02N 2/186; H05K 7/20172; H10N 30/503

(57) ABSTRACT

Vibrational energy produced by fans in electronic devices remain largely untapped. To address this, devices, systems, methods, and processes for harnessing the vibrational energy produced by such fans are described herein. The electronic device includes one or more electronic components and a fan tray. The fan tray includes one or more fans and a housing frame that houses the one or more fans. The one or more fans generate an airflow to cool the one or more electronic components and at least one fan of the one or more fans produces a vibration signal when in operation. The fan tray further includes one or more piezoelectric assemblies disposed relative to the housing frame. The one or more piezoelectric assemblies convert the vibration signal into respective electrical signals. The electrical signals can be converted to direct current (DC) to power the one or more electronic devices.

The present disclosure relates to harnessing vibrational energy in fan trays of communications devices. More particularly, the present disclosure relates to harnessing vibrational energy in fan trays of communications devices using piezoelectric sensors.

### BACKGROUND

Cooling fan trays are essential components in electronic systems, particularly in high-performance devices such as servers, routers, and data centers. These systems generate significant heat due to the high processing power required to handle large volumes of data, computations, or network traffic. Fan trays are designed to provide consistent airflow, drawing cooler air into the system and expelling heated air, thereby maintaining the optimal operating temperature for critical components.

The operation of these cooling fans generates a lot of noise. For example, fan trays typically produce noise in the frequency range of 100 Hz to 10 kHz, with sound levels between 60 and 80 decibels (dB). The frequency and intensity of the noise depend on factors such as the size, speed, and number of fans, as well as the airflow dynamics within the system. Although the noise is a byproduct of cooling, it represents untapped vibrational energy that goes largely wasted. This vibrational energy, produced by the fans, is yet to be harnessed or utilized in existing electronic systems.

### SUMMARY OF THE DISCLOSURE

Systems and methods for harnessing vibrational energy in fan trays of electronic devices using piezoelectric sensors in accordance with embodiments of the disclosure are described herein.

In many embodiments, a fan tray comprises a housing frame, one or more fans housed in the housing frame, and one or more piezoelectric assemblies disposed relative to the housing frame. The one or more fans are configured to generate a cooling airflow, where at least one fan of the one or more fans may produce a vibration signal when in operation. The one or more piezoelectric assemblies are configured to convert the vibration signal into respective electrical signals.

In a number of embodiments, a piezoelectric assembly of the one or more piezoelectric assemblies is disposed on an inner surface of the housing frame.

In a variety of embodiments, the piezoelectric assembly allows unobstructed airflow from the one or more fans.

In more embodiments, a piezoelectric assembly of the one or more piezoelectric assemblies is disposed on an outer surface of the housing frame.

In several embodiments, the vibration signal is produced as sound waves.

In numerous embodiments, a piezoelectric assembly of the one or more piezoelectric assemblies comprises a set of piezoelectric transducer layers.

In further embodiments, a piezoelectric transducer layer of the set of piezoelectric transducer layers comprises one or more piezoelectric elements that convert the vibration signal into an electrical signal of the respective electrical signals.

In additional embodiments, at least one piezoelectric element of the one or more piezoelectric elements is circular in shape.

In various embodiments, at least one piezoelectric element of the one or more piezoelectric elements is rectangular in shape.

In yet more embodiments, the piezoelectric transducer layer further comprises a dielectric sheet and a conducting material disposed on the dielectric sheet. The one or more piezoelectric elements are disposed on the dielectric sheet and coupled to the conducting material.

In still more embodiments, the dielectric sheet comprises a dielectric material that has sound damping effect.

In still yet more embodiments, the conducting material is disposed on a peripheral area of the dielectric sheet.

In many further embodiments, the set of piezoelectric transducer layers comprises a stack of piezoelectric transducer layers with the one or more piezoelectric elements being sandwiched between the dielectric sheet and another dielectric sheet of an adjacent piezoelectric transducer layer in the stack of piezoelectric transducer layers.

In many additional embodiments, the piezoelectric assembly further comprises at least two metal frames.

In numerous additional embodiments, the set of piezoelectric transducer layers is sandwiched between the at least two metal frames.

In several additional embodiments, the at least two metal frames are configured to resonate when subjected to the vibration signal.

In yet many embodiments, an electronic device comprises one or more electronic components and a fan tray. The fan tray comprises a housing frame, one or more fans housed in the housing frame, and one or more piezoelectric assemblies disposed relative to the housing frame. The one or more fans are configured to generate an airflow to cool the one or more electronic components, where at least one fan of the one or more fans may produce a vibration signal when in operation. The one or more piezoelectric assemblies are configured to convert the vibration signal into respective electrical signals.

In many more embodiments, the electronic device further comprises a bus bar configured to power the electronic device, an adder circuit coupled to the one or more piezoelectric assemblies, and a power convertor circuit. The adder circuit is configured to receive the respective electrical signals, and output a combined electrical signal based on the received respective electrical signals. The power convertor circuit is configured to receive the combined electrical signal, transform the combined electrical signal to a Direct Current (DC) signal, and provide the DC signal to the bus bar.

In yet further embodiments, the electronic device further comprises a power supply unit coupled to the bus bar, and a control logic. The power supply unit is configured to generate an output signal. The control logic is configured to control enabling or disabling of the power convertor circuit based on the output signal. The control logic enables the power convertor circuit in response to the output signal being greater than a first threshold value, or disables the power convertor circuit in response to the output signal being below a second threshold value.

In still further embodiments, a method comprises monitoring an output signal of a power supply unit in an electronic device, comparing the monitored output signal with one or more threshold values, and controlling, based on the comparison of the monitored output signal with the one or more threshold values, a supply of piezo-power from one or more piezoelectric assemblies disposed relative to a fan tray of the electronic device. The piezo-power is based on a vibration signal produced by at least one fan housed in the fan tray.

Other objects, advantages, novel features, and further scope of applicability of the present disclosure will be set forth in part in the detailed description to follow, and in part will become apparent to those skilled in the art upon examination of the following or may be learned by practice of the disclosure. Although the description above contains many specificities, these should not be construed as limiting the scope of the disclosure but as merely providing illustrations of some of the presently preferred embodiments of the disclosure. As such, various other embodiments are possible within its scope. Accordingly, the scope of the disclosure should be determined not by the embodiments illustrated, but by the appended claims and their equivalents.

### BRIEF DESCRIPTION OF DRAWINGS

The above, and other, aspects, features, and advantages of several embodiments of the present disclosure will be more apparent from the following description as presented in conjunction with the following several figures of the drawings.

FIG. 1 is a schematic diagram that illustrates a perspective view of an example embodiment of an electronic device including a fan tray apparatus in accordance with various embodiments of the disclosure;

FIG. 2 is a schematic diagram that illustrates a sectional view of a fan tray in accordance with various embodiments of the disclosure;

FIG. 3 is a schematic diagram that illustrates a side view of a fan tray in accordance with various embodiments of the disclosure;

FIG. 4 is a schematic diagram that illustrates a perspective view of a piezoelectric assembly in accordance with various embodiments of the disclosure;

FIG. 5 is a schematic diagram that illustrates a perspective view of a multi-layered piezoelectric assembly in accordance with various embodiments of the disclosure;

FIG. 6 is a schematic diagram that illustrates a cross-sectional view of a piezoelectric assembly in accordance with various embodiments of the disclosure;

FIG. 7 is a schematic diagram that illustrates a cross-sectional view of a fan tray in accordance with various embodiments of the disclosure;

FIG. 8 is a block diagram that illustrates an example electronic device with energy harvesting capability in accordance with various embodiments of the disclosure;

FIG. 9 is a block diagram that illustrates an electronic device with energy harvesting capability in accordance with various embodiments of the disclosure;

FIG. 10 is a block diagram that illustrates supply of piezo-power from multiple piezoelectric assemblies included in a fan tray of an electronic device in accordance with various embodiments of the disclosure;

FIG. 11 is a flowchart showing a process for controlling a supply of piezo-power generated by one or more piezoelectric assemblies included in a fan tray of an electronic device in accordance with various embodiments of the disclosure;

FIG. 12 is a flowchart showing a process for controlling a supply of piezo-power generated by one or more piezoelectric assemblies in accordance with various embodiments of the disclosure; and

FIG. 13 is a conceptual block diagram of a device suitable for configuration with a control logic in accordance with various embodiments of the disclosure.

Corresponding reference characters indicate corresponding components throughout the several figures of the drawings. Elements in the several figures are illustrated for simplicity and clarity and have not necessarily been drawn to scale. For example, the dimensions of some of the elements in the figures might be emphasized relative to other elements for facilitating understanding of the various presently disclosed embodiments. In addition, common, but well-understood, elements that are useful or necessary in a commercially feasible embodiment are often not depicted in order to facilitate a less obstructed view of these various embodiments of the present disclosure.

### DETAILED DESCRIPTION

In response to the issues described above, devices and methods are discussed herein to harness vibrational energy in fan trays of electronic devices, for example, network communications devices, using piezoelectric sensors. Cooling fan trays are very important in electronic systems, particularly in high-performance network devices such as servers, routers, switches, and data centers. The electronic systems generate considerable heat due to the heavy processing demands required to manage vast amounts of data, perform computations, or handle network traffic. Fan trays ensure stable operation by providing continuous airflow, which cools internal components. By drawing in cooler air and expelling the air heated by these components, fan trays help maintain optimal temperatures and prevent overheating.

However, the operation of fans in the fan trays also produces significant noise. For example, fans in the fan trays can emit sound within the frequency range of 100 Hz to 10 kHz, with sound levels ranging between 60 and 80 decibels (dB). The frequency and intensity of the noise depend on variables such as fan size, speed, blade design, or the overall system design. While this noise is traditionally viewed as a mere side effect of cooling, it actually represents untapped vibrational energy that currently goes to waste. In most electronic systems, this energy remains unused, presenting an opportunity for energy recovery through energy harvesting methodologies.

The present disclosure provides a fan tray configured with an energy harvesting functionality to facilitate harnessing of the vibrational energy produced by one or more cooling fans in the fan tray. The energy harvesting functionality can be realized by utilizing piezoelectric sensors. In many embodiments, the fan tray may include a housing frame. In a variety of embodiments, the housing frame may be configured to house one or more fans. The one or more fans may be configured to generate a cooling airflow and at least one fan of the one or more fans may produce a vibration signal, for example, through sound waves, when in operation. In a number of embodiments, the fan tray may further include one or more piezoelectric assemblies disposed relative to the housing frame. The one or more piezoelectric assemblies may be configured to convert the vibration signal into respective electrical signals. The one or more piezoelectric assemblies may act as energy harvesters to capture ambient vibrations or noise and convert them into usable electricity, especially useful in powering low-power applications such as wireless sensors, wearable devices, or the like.

In still more embodiments, a piezoelectric assembly of the one or more piezoelectric assemblies can be disposed on an inner surface of the housing frame, in a manner that the piezoelectric assembly may allow unobstructed airflow from the one or more fans. In still further embodiments, a piezoelectric assembly of the one or more piezoelectric assemblies can be disposed on an outer surface of the housing frame. Thus, allowing the piezoelectric assembly to directly capture vibrations or mechanical stress from the surrounding environment, for example, the one or more cooling fans and other elements external to the fan tray. This external placement may optimize the ability of the piezoelectric assembly to harness energy without interfering with internal components of the fan tray. In various embodiments, the fan tray can have multiple piezoelectric assemblies disposed at different positions relative to the housing frame. For example, some piezoelectric assemblies can be disposed on various inner surfaces of the housing frame that face the one or more fans and some other piezoelectric assemblies can be disposed on various outer surfaces of the housing frame that face away from the one or more fans.

In more embodiments, a piezoelectric assembly of the one or more piezoelectric assemblies may include a set of piezoelectric transducer layers. In yet various embodiments, a piezoelectric transducer layer of the set of piezoelectric transducer layers may include one or more piezoelectric elements that convert the vibration signal into an electrical signal. A “piezoelectric element” may include one or more materials that generate electric charge when subjected to mechanical stress or change shape when subjected to an electric field. The one or more materials may include ceramics (such as lead zirconate titanate), quartz crystals, or specific polymers, in various shapes and sizes, including discs, rings, and films.

In some embodiments, these piezoelectric elements can be directly disposed on the outer surface, the inner surface of the housing frame, or any other suitable position relative to the housing frame, as the piezoelectric transducer layer. In some more embodiments, the one or more piezoelectric elements may be designed in various shapes and sizes, for example, circular shape, rectangular shape, oval shape, square shape, etc., enabling greater flexibility in their application to fit different surfaces and mechanical configurations, depending on the specific design requirements.

In certain embodiments, in addition to the piezoelectric elements, the piezoelectric transducer layer may include a dielectric sheet and a conducting material disposed on the dielectric sheet. In such embodiments, the one or more piezoelectric elements may be disposed on the dielectric sheet and coupled to the conducting material. The dielectric sheet may be composed of a dielectric material that may have a sound damping effect. A “dielectric material” may refer to an insulating substance that does not conduct electricity but can store and separate electric charges. In other words, the dielectric sheet may reduce the noise generated by sound vibrations. Examples of various dielectric materials may include, but not limited to, air, ceramics, glass, Teflon, mica, or the like. In still yet more embodiments, the conducting material may be disposed on a peripheral area of the dielectric sheet. Examples of conducting materials may include, but not limited to, copper, aluminum, silver, or the like. Further, the piezoelectric transducer layer including the dielectric sheet may be disposed in a manner that the dielectric sheet faces the housing frame and the piezoelectric elements may face the fan.

In still yet more embodiments, the set of piezoelectric transducer layers may include multiple piezoelectric transducer layers that are arranged in a stack. Further, in the stack arrangement, the one or more piezoelectric elements are sandwiched between two dielectric sheets, for example, one dielectric sheet on which the one or more piezoelectric elements are disposed and another in the adjacent piezoelectric transducer layer of the stack. This configuration may form a first piezoelectric transducer layer. Several such configurations may be stacked one on top of the other to form the stack of piezoelectric transducer layers.

In many further embodiments, the piezoelectric assembly can include at least two metal frames such that the set of piezoelectric transducer layers are sandwiched between the two metal frames. In many additional embodiments, the metal frames may be configured to resonate when subjected to the vibration signal. In still yet further embodiments, the metal frames may be configured with one or more cut-outs to generate the resonance. The one or more cut-outs may be formed at peripheral portions of the metal frames. The cut-outs may vary in shape and size, including square, rectangular, circular, oval, elliptical, or similar forms. These cut-outs, which can take the form of holes, vents, slots, or other configurations, may be created in the metal frames to enhance the resonance of the metal frames when exposed to the vibration signal. In other words, the metal frames are configured to resonate when subjected to the vibration signal, further enhancing the energy harnessing efficiency of the piezoelectric assembly.

In still yet additional embodiments, the fan tray having the one or more piezoelectric assemblies may be included in an electronic device. The electronic device may further include one or more electronic components that require cooling and the fans in the fan tray may generate the airflow to cool these electronic components. In yet more embodiments, the electronic device may further include a bus bar, an adder circuit coupled to the one or more piezoelectric assemblies, and a power convertor circuit. The bus bar may be configured to power the electronic device. The adder circuit may be configured to receive the respective electrical signals from the piezoelectric assemblies and output a combined electrical signal based on the respective electrical signals. The power converter circuit may receive the combined electrical signal, transform the combined electrical signal to a Direct Current (DC) signal, and provide the DC signal to the bus bar to further power the electronic device.

In several embodiments, the electronic device may further include a power supply unit (PSU) coupled to the bus bar. The PSU may generate an output signal to power the electronic device. The electronic device may also include a control logic that may be configured to control enabling and disabling of the power convertor circuit based on the output signal. This control logic may prevent dumping of excessive current into the bus bar during low load states of the electronic device, thus maximizing PSU efficiency, minimizing PSU damage, and prevent bus bar over voltage conditions when harvesting green energy. Thus, the control logic may enable the power convertor circuit in response to the output signal being greater than a first threshold value, and disable the power convertor circuit in response to the output signal being below a second threshold value. The second threshold value may correspond to the low load state and the first threshold value may correspond to a high load state. By enabling and disabling the power convertor circuit, the control logic may be able to control a supply of piezo-power from the one or more piezoelectric assemblies. For example, if the power convertor circuit is disabled, the supply of the piezo-power from the one or more piezoelectric assemblies is cut-off from the bus bar. Likewise, if the power convertor circuit is enabled, the piezo-power from the one or more piezoelectric assemblies is supplied to the bus bar without interruption. In still yet various embodiments, during the low load state of the electronic device, the piezo-power can be utilized to charge one or more chargeable energy sources, such as batteries, in the electronic device.

Thus, the devices and methods for harnessing vibrational energy produced by cooling fans in fan trays using piezoelectric assemblies offer several advantages. For example, it efficiently converts otherwise wasted vibrational energy into usable power, reducing reliance on external sources, especially for low-energy devices such as sensors. This method is cost-effective, as it leverages existing systems without requiring significant structural modifications, and the compact nature of piezoelectric assemblies allows easy integration into fan trays. Additionally, piezoelectric materials are durable and require minimal maintenance, making them a long-term solution. By capturing sound energy, this technology promotes sustainability and can even slightly reduce noise levels in the system.

Aspects of the present disclosure may be embodied as an apparatus, system, method, or computer program product. Accordingly, aspects of the present disclosure may take the form of an entirely hardware embodiment, an entirely software embodiment (including firmware, resident software, micro-code, or the like) or an embodiment combining software and hardware aspects that may all generally be referred to herein as a “function,” “module,” “apparatus,” or “system.”. Furthermore, aspects of the present disclosure may take the form of a computer program product embodied in one or more non-transitory computer-readable storage media storing computer-readable and/or executable program code. Many of the functional units described in this specification have been labeled as functions, in order to emphasize their implementation independence more particularly. For example, a function may be implemented as a hardware circuit comprising custom VLSI circuits or gate arrays, off-the-shelf semiconductors such as logic chips, transistors, or other discrete components. A function may also be implemented in programmable hardware devices such as via field programmable gate arrays, programmable array logic, programmable logic devices, or the like.

Functions may also be implemented at least partially in software for execution by various types of processors. An identified function of executable code may, for instance, comprise one or more physical or logical blocks of computer instructions that may, for instance, be organized as an object, procedure, or function. Nevertheless, the executables of an identified function need not be physically located together but may comprise disparate instructions stored in different locations which, when joined logically together, comprise the function and achieve the stated purpose for the function.

Indeed, a function of executable code may include a single instruction, or many instructions, and may even be distributed over several different code segments, among different programs, across several storage devices, or the like. Where a function or portions of a function are implemented in software, the software portions may be stored on one or more computer-readable and/or executable storage media. Any combination of one or more computer-readable storage media may be utilized. A computer-readable storage medium may include, for example, but not limited to, an electronic, magnetic, optical, electromagnetic, infrared, or semiconductor system, apparatus, or device, or any suitable combination of the foregoing, but would not include propagating signals. In the context of this document, a computer readable and/or executable storage medium may be any tangible and/or non-transitory medium that may contain or store a program for use by or in connection with an instruction execution system, apparatus, processor, or device.

Computer program code for carrying out operations for aspects of the present disclosure may be written in any combination of one or more programming languages, including an object-oriented programming language such as Python, Java, Smalltalk, C++, C#, Objective C, or the like, conventional procedural programming languages, such as the “C” programming language, scripting programming languages, and/or other similar programming languages. The program code may execute partly or entirely on one or more of a user's computer and/or on a remote computer or server over a data network or the like.

A component, as used herein, comprises a tangible, physical, non-transitory device. For example, a component may be implemented as a hardware logic circuit comprising custom VLSI circuits, gate arrays, or other integrated circuits; off-the-shelf semiconductors such as logic chips, transistors, or other discrete devices; and/or other mechanical or electrical devices. A component may also be implemented in programmable hardware devices such as field programmable gate arrays, programmable array logic, programmable logic devices, or the like. A component may comprise one or more silicon integrated circuit devices (e.g., chips, die, die planes, packages) or other discrete electrical devices, in electrical communication with one or more other components through electrical lines of a printed circuit board (PCB) or the like. Each of the functions and/or modules described herein, in certain embodiments, may alternatively be embodied by or implemented as a component.

A circuit, as used herein, comprises a set of one or more electrical and/or electronic components providing one or more pathways for electrical current. In certain embodiments, a circuit may include a return pathway for electrical current, so that the circuit is a closed loop. In another embodiment, however, a set of components that does not include a return pathway for electrical current may be referred to as a circuit (e.g., an open loop). For example, an integrated circuit may be referred to as a circuit regardless of whether the integrated circuit is coupled to ground (as a return pathway for electrical current) or not. In various embodiments, a circuit may include a portion of an integrated circuit, an integrated circuit, a set of integrated circuits, a set of non-integrated electrical and/or electrical components with or without integrated circuit devices, or the like. In one embodiment, a circuit may include custom VLSI circuits, gate arrays, logic circuits, or other integrated circuits; off-the-shelf semiconductors such as logic chips, transistors, or other discrete devices; and/or other mechanical or electrical devices. A circuit may also be implemented as a synthesized circuit in a programmable hardware device such as field programmable gate array, programmable array logic, programmable logic device, or the like (e.g., as firmware, a netlist, or the like). A circuit may comprise one or more silicon integrated circuit devices (e.g., chips, die, die planes, packages) or other discrete electrical devices, in electrical communication with one or more other components through electrical lines of a printed circuit board (PCB) or the like. Each of the functions and/or modules described herein, in certain embodiments, may be embodied by or implemented as a circuit. Reference throughout this specification to “one embodiment,” “an embodiment,” or similar language means that a particular feature, structure, or characteristic described in connection with the embodiment is included in at least one embodiment of the present disclosure. Thus, appearances of the phrases “in one embodiment,” “in an embodiment,” and similar language throughout this specification may, but do not necessarily, all refer to the same embodiment, but mean “one or more but not all embodiments” unless expressly specified otherwise. The terms “including,” “comprising,” “having,” and variations thereof mean “including but not limited to”, unless expressly specified otherwise. An enumerated listing of items does not imply that any or all of the items are mutually exclusive and/or mutually inclusive, unless expressly specified otherwise. The terms “a,” “an,” and “the” also refer to “one or more” unless expressly specified otherwise.

Further, as used herein, reference to reading, writing, storing, buffering, and/or transferring data can include the entirety of the data, a portion of the data, a set of the data, and/or a subset of the data. Likewise, reference to reading, writing, storing, buffering, and/or transferring non-host data can include the entirety of the non-host data, a portion of the non-host data, a set of the non-host data, and/or a subset of the non-host data. Lastly, the terms “or” and “and/or” as used herein are to be interpreted as inclusive or meaning any one or any combination. Therefore, “A, B or C” or “A, B and/or C” mean “any of the following: A; B; C; A and B; A and C; B and C; A, B and C.”. An exception to this definition will occur only when a combination of elements, functions, steps, or acts are in some way inherently mutually exclusive.

Aspects of the present disclosure are described below with reference to schematic flowchart diagrams and/or schematic block diagrams of methods, apparatuses, systems, and computer program products according to embodiments of the disclosure. It will be understood that each block of the schematic flowchart diagrams and/or schematic block diagrams, and combinations of blocks in the schematic flowchart diagrams and/or schematic block diagrams, can be implemented by computer program instructions. These computer program instructions may be provided to a processor of a computer or other programmable data processing apparatus to produce a machine, such that the instructions, which execute via the processor or other programmable data processing apparatus, create means for implementing the functions and/or acts specified in the schematic flowchart diagrams and/or schematic block diagrams block or blocks.

It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. Other steps and methods may be conceived that are equivalent in function, logic, or effect to one or more blocks, or portions thereof, of the illustrated figures. Although various arrow types and line types may be employed in the flowchart and/or block diagrams, they are understood not to limit the scope of the corresponding embodiments. For instance, an arrow may indicate a waiting or monitoring period of unspecified duration between enumerated steps of the depicted embodiment.

In the following detailed description, reference is made to the accompanying drawings, which form a part thereof. The foregoing summary is illustrative only and is not intended to be in any way limiting. In addition to the illustrative aspects, embodiments, and features described above, further aspects, embodiments, and features will become apparent by reference to the drawings and the following detailed description. The description of elements in each figure may refer to elements of proceeding figures. Like numbers may refer to like elements in the figures, including alternate embodiments of like elements.

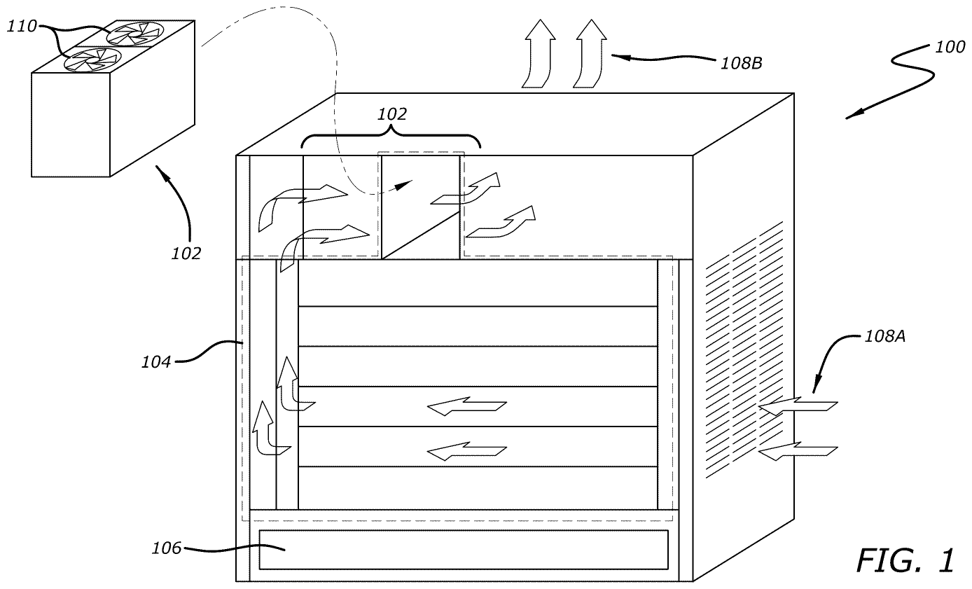

Referring to FIG. 1, a schematic diagram that illustrates a perspective view of an example electronic device 100 including one or more fan trays in accordance with various embodiments of the disclosure is shown. In various networking devices, such as switches, routers, servers, load balancers, firewalls, data center rack, etc., efficient cooling is essential to ensure proper functioning of its components. The embodiments of FIG. 1 describe one such electronic device 100 that includes one or more fan trays 102. The electronic device 100 may further include several electronic components 104 that require cooling and one or more power supply units (PSUs) 106.

In a variety of embodiments, each of the fan tray(s) 102 may house one or more fans 110. The fan(s) 110 may be configured to generate an airflow that cools the electronic device 100 by drawing cool air through a chassis of the electronic device 100 and expelling the hot air that builds up around the electronic components 104. The fan(s) 110 may be strategically placed to ensure that the heat-sensitive areas, such as processors and power supplies, receive adequate airflow.

In a number of embodiments, the electronic components 104 may include, for example central processing units (CPUs), graphics processing units (GPUs), memory modules, network interface cards, or the like, which generate significant amounts of heat during operation. The cooling provided by the fan tray(s) 102 may maintain the temperature of the electronic components 104 within specified thermal thresholds, preventing overheating that could lead to reduced performance or hardware failure.

In a variety of embodiments, the PSUs 106 may be configured to provide the necessary electrical power to all the electronic components 104 of the electronic device 100. Like the other components, the PSUs 106 may also generate heat during operation, particularly under heavy loads. Effective cooling may ensure that the PSUs 106 operate efficiently and do not overheat.

In more embodiments, airflow within the electronic device 100 may be typically directed in a front-to-back or top-to-bottom configuration. An example embodiment of an incoming airflow 108A drawn into the electronic device 100 by the fan tray(s) 102 through intake vents is shown in FIG. 1. The fan tray(s) 102 may be configured to distribute this cooler air over the electronic components 104, absorbing the heat generated by them. As the air heats up, it is expelled as outgoing airflow 108B through exhaust vents, for example at the back of the chassis. This continuous cycle of incoming cool air and outgoing hot air ensures that the internal temperature is regulated and prevents heat buildup around critical components.

In additional embodiments, the fan tray(s) 102 may be the primary drivers of airflow within the electronic device 100. Each fan 110 inside the fan tray(s) 102 may operate at a speed proportional to the cooling requirements. Sensors embedded within the electronic device 100 may monitor the temperature of the electronic components 104 and adjust the speed of the fan(s) 110 to meet the demand. For instance, if the temperature of the CPU, or PSUs rise due to high processing loads, the fan(s) 110 may increase fan speed to move more air and dissipate the excess heat. As the fan(s) 110 operate to cool the electronic components 104, the fan(s) 110 may produce consistent noise (e.g., sound waves) and vibrations (e.g., vibration signals) in the air. The frequency and intensity of the noise may depend on various factors such as fan size, speed, blade design, or the overall system design.

In further embodiments, in addition to the fan(s) 110, the fan tray(s) 102 may include one or more piezoelectric assemblies to convert the vibration signals produced by the fan(s) 110 into electrical energy. The vibration signals produced due to the sound waves create mechanical stress in the piezoelectric materials of the one or more piezoelectric assemblies. When the one or more piezoelectric assemblies are subjected to these vibrations, the one or more piezoelectric assemblies may undergo deformation, producing an electrical charge due to the piezoelectric effect. This allows the one or more piezoelectric assemblies to harness the vibrational energy in the noise produced by the fan(s) 110 and convert it into usable electrical energy, while the fan(s) 110 continue their primary function of cooling the electronic components 104.

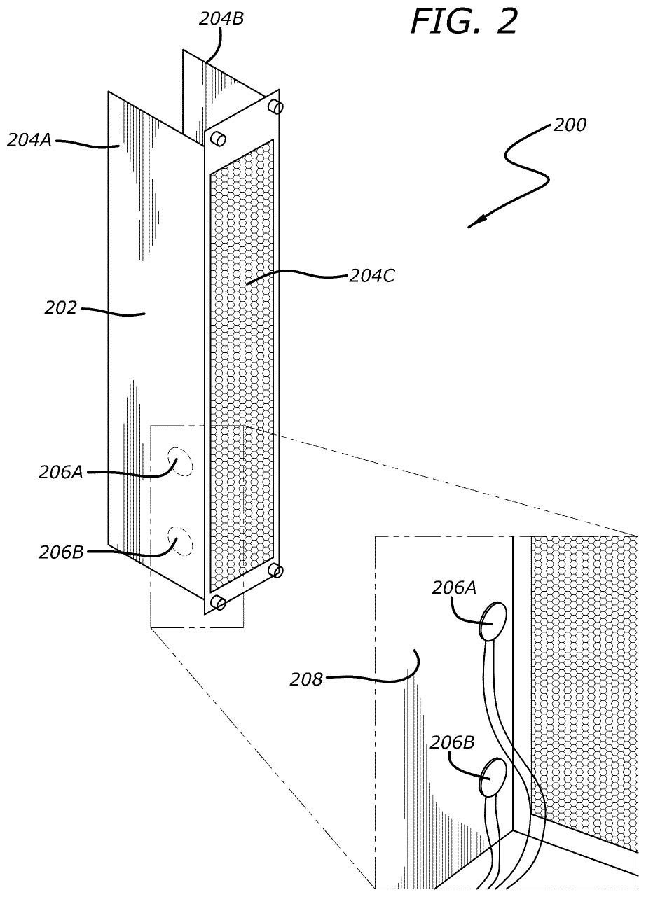

Although a specific embodiment for an electronic device 100 including a fan tray apparatus suitable for carrying out the various steps, processes, methods, and operations described herein is discussed with respect to FIG. 1, any of a variety of systems and/or processes may be utilized in accordance with embodiments of the disclosure. For example, the one or more piezoelectric assemblies may be disposed relative to a housing frame of the fan tray(s) 102. The elements depicted in FIG. 1 may also be interchangeable with other elements of FIGS. 2-13 as required to realize a particularly desired embodiment.

Referring to FIG. 2, a schematic diagram that illustrates a sectional view of a fan tray 200 in accordance with various embodiments of the disclosure is shown. In many embodiments, the fan tray 200 may be included in an electronic device to regulate temperature by directing airflow over electronic components in the electronic device. The fan tray 200 may include a housing frame 202. In the example shown in FIG. 2, the housing frame 202 is shown as a three-walled enclosure including a first wall 204A, a second wall 204B, and a third wall 204C, each side serving a specific function to house and support a fan mechanism. The first wall 204A and the second wall 204B may be two opposing walls that are connected by the third wall 204C at one edge. Further, in an example, the third wall 204C may be featured with a series of meshed vents that extend across its surface for airflow management. In other words, the meshed vents may allow the air to pass freely through the fan tray 200 based on the operation of the fan mechanism. As one or more fans of the fan mechanism operate and generate the cooling airflow, they also produce noise, for example, due to air turbulence, blade design, mechanical vibrations, etc. Noise is essentially sound waves, which are pressure variations caused by mechanical vibrations. These vibration signals propagate through the air as acoustic signals.

In a number of embodiments, the fan tray 200 may further include one or more piezoelectric assemblies disposed relative to the housing frame 202 to harness the vibrational energy. A piezoelectric assembly may include a piezoelectric transducer layer having one or more piezoelectric elements. The piezoelectric elements may convert the vibration signals produced by the fans into electrical signals. Examples of piezoelectric material utilized in the piezoelectric elements may include, but not limited to, ceramics (such as lead zirconate titanate), quartz crystals, or specific polymers.

As shown in FIG. 2, the piezoelectric transducer layer comprises piezoelectric elements 206A and 206B disposed on an inner surface 208 of the first wall 204A. In an example, the piezoelectric elements 206A and 206B can be directly disposed on the inner surface 208. The piezoelectric elements 206A and 206B may be strategically placed on the inner surface 208 to capture the vibrations signals produced by the fans without interfering with the airflow. By disposing the piezoelectric assembly on the inner surface 208 of the housing frame 202, the vibrational energy produced by the fans is efficiently harnessed. Though FIG. 2 illustrates two piezoelectric elements 206A and 206B included in the piezoelectric transducer layer, the scope of the disclosure is not limited to it. The piezoelectric transducer layer can have as many piezoelectric elements as required.

In several embodiments, the piezoelectric elements 206A and 206B can be connected to appropriate conductive wiring system to efficiently transfer the generated electric signal. By integrating the piezoelectric elements 206A and 206B with suitable conducting circuits, the electric signal generated through the piezoelectric effect can be captured and routed for various powering applications. In additional embodiments, additional piezoelectric assemblies can also be disposed on an inner surface of the second wall 204B.

Although a specific embodiment for a sectional view of the fan tray 200 suitable for carrying out the various steps, processes, methods, and operations described herein is discussed with respect to FIG. 2, any of a variety of systems and/or processes may be utilized in accordance with embodiments of the disclosure. Though the piezoelectric elements 206A and 206B are shown to be in circular shape. The scope of the disclosure is not limited to it. In some more embodiments, the piezoelectric elements 206A and 206B can be designed in various shapes and sizes, for example, rectangular shape, oval shape, square shape, etc., enabling greater flexibility in their application to fit different surfaces and mechanical configurations, depending on the specific design requirements. The elements depicted in FIG. 2 may also be interchangeable with other elements of FIG. 1 and FIGS. 3-13 as required to realize a particularly desired embodiment.

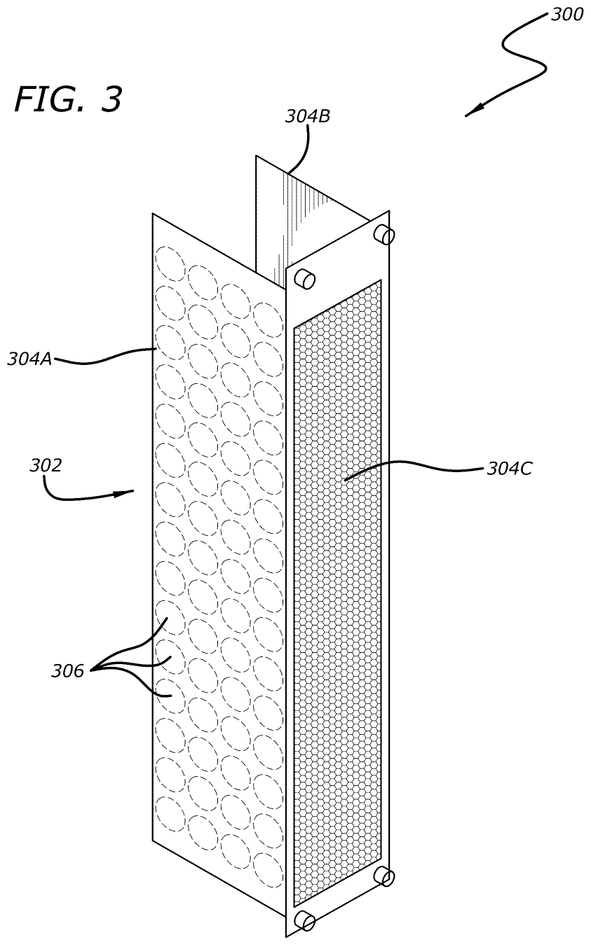

Referring to FIG. 3, a schematic diagram that illustrates a side view of a fan tray 300 in accordance with various embodiments of the disclosure is shown. In many embodiments, the fan tray 300 may be included in an electronic device to regulate temperature by directing airflow over electronic components in the electronic device. The fan tray 300 may include a housing frame 302 that houses a fan mechanism. In the example shown in FIG. 3, the housing frame 302 is shown as a three-walled enclosure, including a first wall 304A, a second wall 304B, and a third wall 304C, to house and support the fan mechanism. As one or more fans of the fan mechanism operate, in addition to generating the cooling airflow, they also produce vibration signals in the form of noise.

In a number of embodiments, the fan tray 300 may further include one or more piezoelectric assemblies disposed relative to the housing frame 302 to harness the vibrational energy. A piezoelectric assembly may include a piezoelectric transducer layer having one or more piezoelectric elements. As shown in FIG. 3, the piezoelectric transducer layer comprises piezoelectric elements 306 disposed on an outer surface of the first wall 304A. In an example, the piezoelectric elements 306 can be directly disposed on the outer surface of the first wall 304A.

In more embodiments, the piezoelectric assembly, including the piezoelectric elements 306, can also be strategically placed on the outer surface of the second wall 304B to capture mechanical vibrations generated by the operation of the fans housed within the housing frame 302 and other components external to the fan tray 300. In several embodiments, the fan tray 300 can include multiple piezoelectric assemblies which can be disposed at different positions relative to the housing frame 302. For example, some piezoelectric assemblies can be disposed on various inner surfaces, of the housing frame 302, facing the one or more fans and some other piezoelectric assemblies can be disposed on various outer surfaces, of the housing frame 302, facing away from the one or more fans.

Although a specific embodiment for a side view of the fan tray 300 suitable for carrying out the various steps, processes, methods, and operations described herein is discussed with respect to FIG. 3, any of a variety of systems and/or processes may be utilized in accordance with embodiments of the disclosure. For example, the piezoelectric assemblies can include additional components such as one or more dielectric sheets for enhancing their efficacy. The elements depicted in FIG. 3 may also be interchangeable with other elements of FIGS. 1-2 and FIGS. 4-13 as required to realize a particularly desired embodiment.

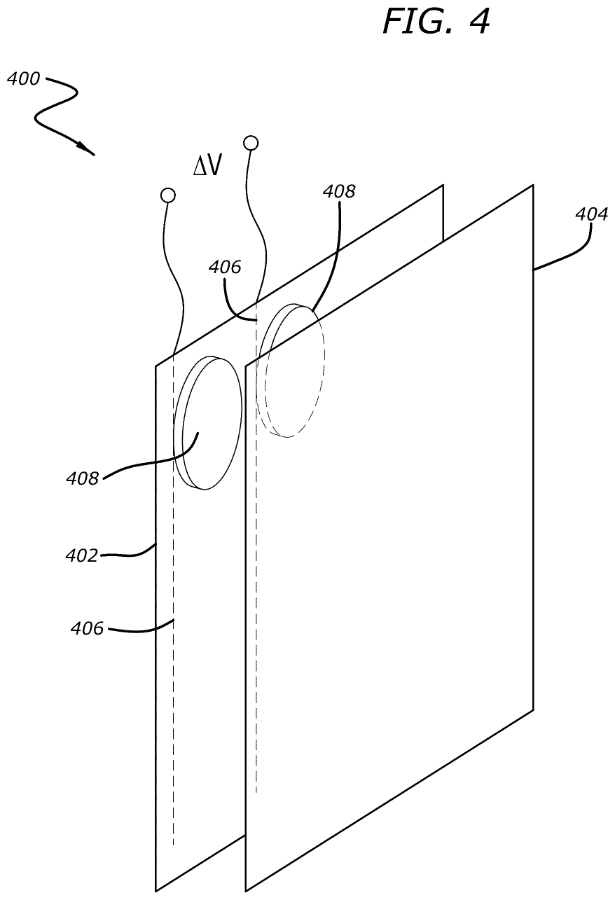

Referring to FIG. 4, a schematic diagram that illustrates a perspective view of a piezoelectric assembly 400 in accordance with various embodiments of the disclosure is shown. In many embodiments, the piezoelectric assembly 400 can be disposed relative to a housing frame of a fan tray to harness vibrational energy produced by various operating fans in the fan tray. For example, the piezoelectric assembly 400 can be disposed on an inner surface of the housing frame, an outer surface of the housing frame, or any other suitable position within or outside the housing frame to convert vibration signals produced by the operating fans to electrical signals.

In various embodiments, the piezoelectric assembly 400 may include a set of piezoelectric transducer layers. In the example shown in FIG. 4, the piezoelectric assembly 400 includes a single piezoelectric transducer layer. The piezoelectric transducer layer may include a first dielectric sheet 402, a second dielectric sheet 404, a conducting material 406, and one or more piezoelectric elements 408.

In a number of embodiments, the conducting material 406 may be disposed on the first dielectric sheet 402. For example, the conducting material 406 may be disposed directly on a surface of the first dielectric sheet 402, allowing for electrical pathways or connections to external circuits. The conducting material 406 can be disposed as a conducting frame, a conducting sheet, a conducting ring, or a conducting filament on the first dielectric sheet 402. In still more embodiments, the piezoelectric elements 408 may also be disposed on the first dielectric sheet 402 such that the conducting material 406 is connected to the piezoelectric elements 408. In additional embodiments, the second dielectric sheet 404 may be disposed on top of the piezoelectric elements 408 such that the piezoelectric elements 408 are sandwiched between the first dielectric sheet 402 and the second dielectric sheet 404. In still additional embodiments, the second dielectric sheet 404 may be utilized as a cover for the piezoelectric elements 408.

In response to the piezoelectric elements 408 being subjected to mechanical stress due to the vibration signals produced by the fans, the piezoelectric elements 408 generate electrical charges through piezoelectric effect. The conducting material 406 on the first dielectric sheet 402 may transmit the generated electrical charge to an external circuit. The first dielectric sheet 402 and the second dielectric sheet 404 may serve as insulating layers that do not conduct electricity. In other words, the conducting material 406 may transfer the electrical signals (denoted as “ΔV” in FIG. 4) or charges to and from the piezoelectric elements 408, while the first dielectric sheet 402 and the second dielectric sheet 404 provide electrical isolation to the piezoelectric elements 408.

Although a specific embodiment of a perspective view of a piezoelectric assembly 400 suitable for carrying out the various steps, processes, methods, and operations described herein is discussed with respect to FIG. 4, any of a variety of systems and/or processes may be utilized in accordance with embodiments of the disclosure. For example, a piezoelectric assembly can include multiple piezoelectric transducer layers. The elements depicted in FIG. 4 may also be interchangeable with other elements of FIGS. 1-3 and FIGS. 5-13 as required to realize a particularly desired embodiment.

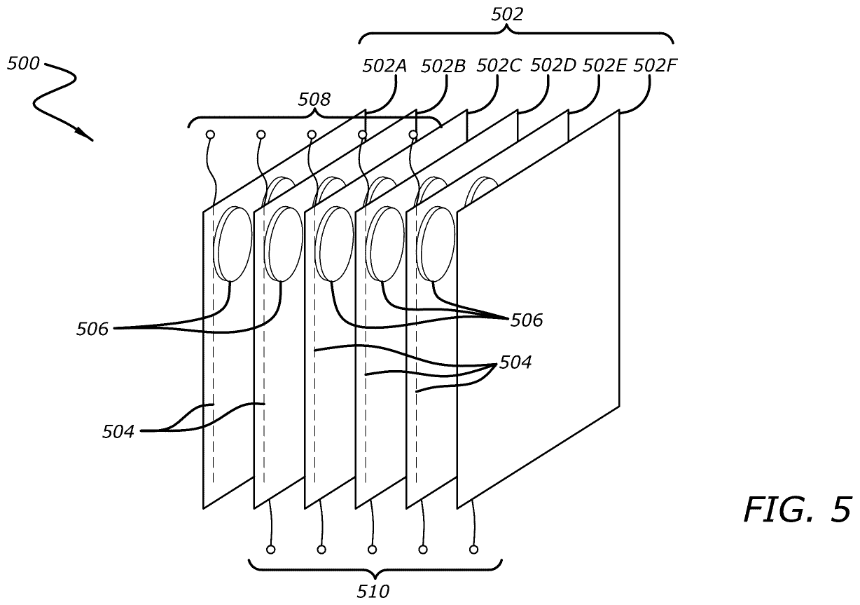

Referring to FIG. 5, a schematic diagram that illustrates a perspective view of a multi-layered piezoelectric assembly 500 in accordance with various embodiments of the disclosure is shown. In many embodiments, the multi-layered piezoelectric assembly 500 can be disposed relative to a housing frame of a fan tray to harness vibrational energy produced by various operating fans in the fan tray. For example, the multi-layered piezoelectric assembly 500 can be disposed on an inner surface of the housing frame, an outer surface of the housing frame, or any other suitable position within or outside housing frame to convert vibration signals produced by the operating fans to electrical signals.

In various embodiments, the multi-layered piezoelectric assembly 500 may include multiple dielectric sheets 502A, 502B, 502C, 502D, 502E that have conducting material 504 and piezoelectric elements 506 disposed thereon. Further, the piezoelectric elements 506 disposed on (or distributed on) each dielectric sheet 502A, 502B, 502C, 502D, 502E are electrically connected to the conducting material 504 disposed on respective dielectric sheets 502A, 502B, 502C, 502D, 502E. A dielectric sheet having conducting material 504 and piezoelectric elements 506 disposed thereon may be referred to as a piezoelectric transducer layer. Thus, the multi-layered piezoelectric assembly 500 may have multiple piezoelectric transducer layers formed by these dielectric sheets 502A, 502B, 502C, 502D, 502E having the conducting material 504 and the piezoelectric elements 506 disposed thereon.

In yet further embodiments, the piezoelectric transducer layers may be bonded and arranged in a stack. In other words, the piezoelectric assembly 500 may include a stack of piezoelectric transducer layers. In the stack arrangement, the piezoelectric elements 506 in one piezoelectric transducer layer may face and potentially interact with a dielectric sheet of adjacent piezoelectric transducer layer. In other words, the piezoelectric elements 506 disposed on one dielectric sheet are sandwiched between the respective dielectric sheet and the dielectric sheet of the adjacent piezoelectric transducer layer. For example, the piezoelectric elements 506 disposed on the dielectric sheet 502A are sandwiched between the dielectric sheets 502A and 502B. Further, an opposing surface of the dielectric sheet 502B, which does not face the piezoelectric elements 506 disposed on the dielectric sheet 502A, has the piezoelectric elements 506 and the conducting material 504 disposed thereon.

In numerous embodiments, a last dielectric sheet 502F may be configured as an insulting cover for the piezoelectric elements 506 in the last piezoelectric transducer layer, for example disposed on the dielectric sheet 502E. Thus, an opposing surface of the dielectric sheet 502F, which does not face the piezoelectric elements 506 disposed on the dielectric sheet 502E, may not have any piezoelectric elements 506 or conducting material 504 disposed thereon. The dielectric sheets 502A, 502B, 502C, 502D, 502E, 502F are collectively designated as “dielectric sheets 502”.

In several embodiments, the conducting material 504 may include two ends 508 and 510. The end 508 may be connected to a positive terminal of an external circuit and the other end 510 may be connected to a negative terminal of the external circuit or ground. When the multi-layered piezoelectric assembly 500 is subjected to mechanical stress, for example, due to the vibration signal produced by the fans in the fan tray, the multi-layered piezoelectric assembly 500 may generate electrical signals through piezoelectric effect. The two ends 508 and 510 of the conducting material 504 may transmit the generated electrical signals to the external circuit.

Although a specific embodiment of a multi-layered piezoelectric assembly 500 suitable for carrying out the various steps, processes, methods, and operations described herein is discussed with respect to FIG. 5, any of a variety of systems and/or processes may be utilized in accordance with embodiments of the disclosure. For example, a piezoelectric assembly can include a piezoelectric element that is rectangular in shape. The elements depicted in FIG. 5 may also be interchangeable with other elements of FIGS. 1-4 and FIGS. 6-13 as required to realize a particularly desired embodiment.

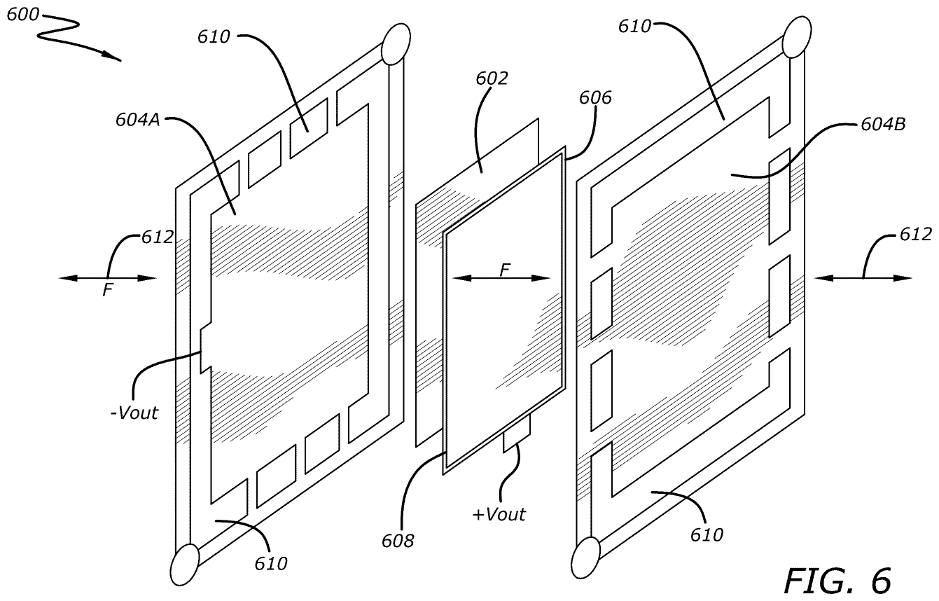

Referring to FIG. 6, a schematic diagram that illustrates a cross-sectional view of a piezoelectric assembly 600 in accordance with various embodiments of the disclosure is shown. In many embodiments, the piezoelectric assembly 600 can be disposed relative to a housing frame of a fan tray to harness vibrational energy produced by various operating fans in the fan tray. For example, the piezoelectric assembly 600 can be disposed on an inner surface of the housing frame, an outer surface of the housing frame, or any other suitable position within or outside housing frame to convert vibration signals produced by the operating fans to an electrical signal.

In various embodiments, the piezoelectric assembly 600 may include a piezoelectric transducer layer sandwiched between two metal frames 604A and 604B. The piezoelectric transducer layer may include a piezoelectric element 602 disposed on a dielectric material 606. Examples of various dielectric materials can include, but not limited to, ceramics, glass, Teflon, mica, or the like. In still more embodiments, the piezoelectric element 602 may be configured in the form of a square or a rectangular sheet. In one or more embodiments, the dielectric material 606 may also have a conductive material disposed thereon. For example, the conductive material may be disposed as a metal ring 608 on the dielectric material 606 and connected to the piezoelectric element 602. In other words, the dielectric material 606 having the piezoelectric element 602 and the metal ring 608 disposed thereon, is bonded to the two metal frames 604A and 604B on opposing sides to form the piezoelectric assembly 600. The design of the two metal frames 604A and 604B may be tailored to match the shape and structure of the piezoelectric element 602. Furthermore, the metal ring 608 may be configured as a square or a rectangular ring to align with the geometry of the piezoelectric element 602.

In further additional embodiments, the metal frames 604A and 604B may be configured with one or more cut-outs 610. The cut-outs 610 may maximize resonate forces of vibration. In several embodiments, the cut-outs 610 may be formed at peripheral portions of the metal frames 604A and 604B. The cut-outs 610 may vary in shape and size, including square, rectangular, circular, oval, elliptical, or similar forms. These cut-outs 610, which can take the form of holes, vents, slots, or other configurations, may be created in the metal frames 604A and 604B to enhance the resonance of the metal frames when exposed to the vibration signal produced by the fans. In other words, the metal frames 604A and 604B are configured to resonate when subjected to the vibration signal, further enhancing the energy harnessing efficiency of the piezoelectric assembly 600.

In further embodiments, the metal frame 604A may include a protrusion serving as a first output terminal (labelled as “−Vout” in FIG. 6) designed to interface with the piezoelectric element 602. Similarly, the metal ring 608 may be configured with a protrusion functioning as a second output terminal (labelled as “+Vout” in FIG. 6) also designed to interface with the piezoelectric element 602.

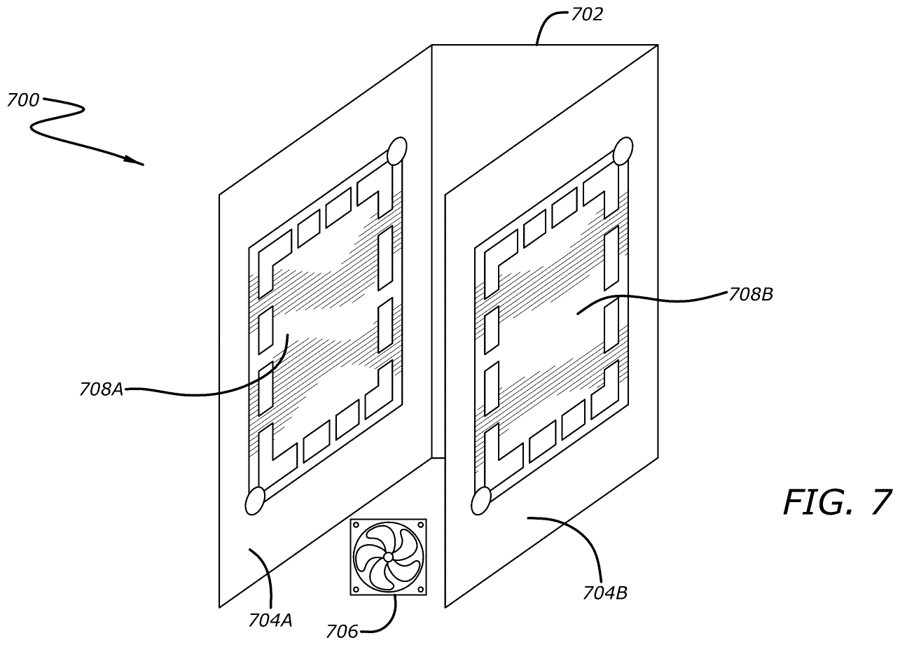

In still additional embodiments, the fans may be configured to operate in proximity to the piezoelectric assembly 600. As the one or more fans start operating, the fans may generate mechanical vibrations, which may be transferred to the piezoelectric element 602. The piezoelectric element 602 may undergo deformation due to the applied mechanical stress and convert the mechanical stress into electrical energy, thereby generating an electric signal. The dielectric material 606 between the first and second output terminals (−Vout and +Vout) may ensure electrical insulation. Further, the generated electric charge may be collected and transferred via the first and second output terminals (−Vout and +Vout) to an output circuit. Mounting of the piezoelectric assembly 600 on a fan tray is described in conjunction with FIG. 7.

In further examples, the dielectric material 606 can also be air. In such embodiments, the metal ring 608 may be designed to directly interface with the piezoelectric element 602. Thus, the piezoelectric element 602 bonded to the metal ring 608 can be further bonded to the two metal frames 604A and 604B on opposing sides to form the piezoelectric assembly 600. Though the piezoelectric element 602 is shown to be rectangular, the scope of the disclosure is not limited to it. The piezoelectric element 602 can have any shape as per system design requirements.

Although a specific embodiment of a piezoelectric assembly 600 suitable for carrying out the various steps, processes, methods, and operations described herein is discussed with respect to FIG. 6, any of a variety of systems and/or processes may be utilized in accordance with embodiments of the disclosure. For example, bonding surface of the metal frames 604A and 604B may be oriented perpendicular to vibration forces “F” 612 to maximize resonant vibrations to the piezoelectric element 602. The elements depicted in FIG. 6 may also be interchangeable with other elements of FIGS. 1-5 and FIGS. 7-13 as required to realize a particularly desired embodiment.

Referring to FIG. 7, a schematic diagram that illustrates a cross-sectional view of a fan tray 700 equipped with multiple piezoelectric assemblies in accordance with various embodiments of the disclosure is shown. In many embodiments, the fan tray 700 may be included in an electronic device to regulate temperature by directing airflow over electronic components in the electronic device. The fan tray 700 may include a housing frame 702 that has a plurality of walls, for example, a first wall 704A, a second wall 704B, and a third wall. The first wall 704A and the second wall 704B may be two opposing walls that are connected by the third wall at one edge. In a number of embodiments, the housing frame 702 may serve as an enclosure for a fan 706. As the fan 706 operates and generates the cooling airflow, the fan 706 may also produce vibration signals that propagate through the air as acoustic signals.

In a variety of embodiments, one or more piezoelectric assemblies may be disposed relative to the housing frame 702. For example, as shown in FIG. 7, a first piezoelectric assembly 708A is disposed on an inner surface of the first wall 704A that faces the fan 706 and a second piezoelectric assembly 708B is disposed on an outer surface of the second wall 704B that faces away from the fan 706. Each of the first piezoelectric assembly 708A and the second piezoelectric assembly 708B may include a set of piezoelectric transducer layers sandwiched between two or more metal frames. The two or more metal frames may be configured with one or more cut-outs.

In more embodiments, additional piezoelectric assemblies can be mounted on both inner and outer surfaces of the first wall 704A and the second wall 704B of the housing frame 702. This dual configuration may enable the piezoelectric assemblies to harness the internal and external mechanical energies (e.g., vibrational energy) efficiently. In yet more embodiments, the first piezoelectric assembly 708A and the second piezoelectric assembly 708B can also be mounted on the inner surfaces of the first wall 704A and the second wall 704B or the outer surfaces of the first wall 704A and the second wall 704B.

Although a specific embodiment for a cross-sectional view of a fan tray 700 suitable for carrying out the various steps, processes, methods, and operations described herein is discussed with respect to FIG. 7, any of a variety of systems and/or processes may be utilized in accordance with embodiments of the disclosure. For example, the first piezoelectric assembly 708A and the second piezoelectric assembly 708B can also include the set of piezoelectric transducer layers sandwiched between two or more plastic sheets instead of metal frames. The elements depicted in FIG. 7 may also be interchangeable with other elements of FIGS. 1-6 and FIGS. 8-13 as required to realize a particularly desired embodiment.

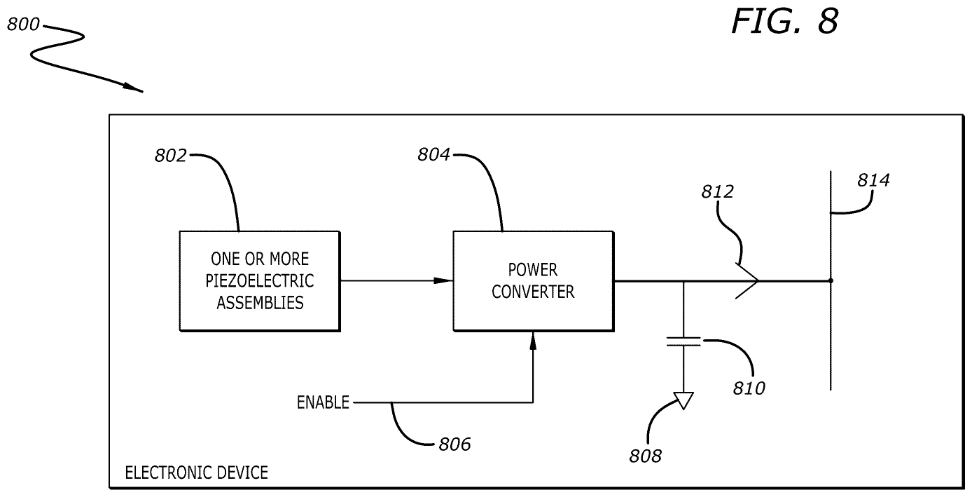

Referring to FIG. 8, a block diagram that illustrates an electronic device with energy harvesting capability in accordance with various embodiments of the disclosure is shown. Having disclosed description of example piezoelectric assemblies in FIGS. 1-7, FIG. 8 depicts an example of an electronic device 800 in which energy harvesting is enabled by way of one or more piezoelectric assemblies 802. As shown in the embodiment depicted in FIG. 8, the electronic device 800 may include the one or more piezoelectric assemblies 802 and a power converter 804 coupled to the one or more piezoelectric assemblies 802. In various embodiments, the one or more piezoelectric assemblies 802 may be included in a fan tray of the electronic device 800. For example, the one or more piezoelectric assemblies 802 can be disposed relative to a housing frame of the fan tray to harness vibrational energy produced by various operating fans in the fan tray.

The power converter 804 may include suitable logic, circuitry, and/or interfaces to convert electrical signals into Direct Current (DC) signals. The power converter 804 may be controlled through an enable signal 806. The enable signal 806 may be a control input that may enable or disable the operation of the power converter 804. For example, if the enable signal 806 is high (or active), the power converter 804 may convert electrical signals into DC signals. Conversely, if the enable signal is low (or inactive), the power converter 804 may be disabled and may effectively stop the power conversion process.

In number of embodiments, an output terminal of the power converter 804 may be coupled to a bus bar 814. Further, the output terminal of the power converter 804 may further be signal grounded 808 via a capacitor 810 to smooth out voltage fluctuations or transients in the DC signals. A “bus bar” may refer to a conductive wiring utilized for distributing electric current in an electronic device.

In response to the one or more piezoelectric assemblies 802 being subjected to vibrational stress caused by a vibrational signal produced by a fan in the fan tray, the one or more piezoelectric assemblies 802 may convert the vibrational signal into electrical signals. The power converter 804 may receive the electrical signals. In a case where the enable signal 806 is high, the power converter 804 may transform the electrical signals to DC signal 812 and provide to the bus bar 814. However, in another case where the enable signal 806 is low, the power converter 804 may be disabled and may not transform the electrical signals to DC signal 812. In other words, the power converter 804 may serve as a switch that can be utilized to control a supply of piezo-power from the one or more piezoelectric assemblies 802 to the bus bar 814. Thus, if the power converter 804 is disabled the supply of piezo-power is cut-off, whereas if the power converter 804 is enabled the piezo-power is supplied to the bus bar 814.

Although specific embodiments for an electronic device with energy harvesting capability are described above with respect to FIG. 8, any of a variety of systems and/or processes may be utilized in accordance with embodiments of the disclosure. For example, the power converter 804 can be additionally coupled to one or more chargeable energy sources. In such a scenario, if the enable signal 806 is low, instead of providing the DC signal 812 to the bus bar 814, the power converter 804 can provide the DC signal 812 to the one or more chargeable energy sources for energy storage. The elements depicted in FIG. 8 may also be interchangeable with other elements of FIGS. 1-7 and 9-13 as required to realize a particularly desired embodiment. More details about sustainability aware call routing are described below.

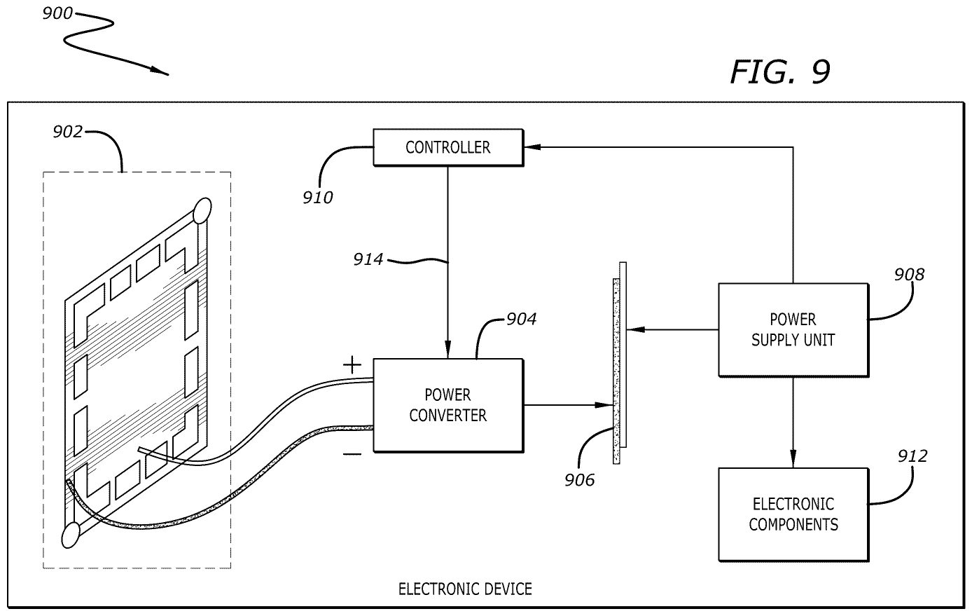

Referring to FIG. 9, a block diagram that illustrates an electronic device with energy harvesting capability in accordance with various embodiments of the disclosure. Having disclosed description of example piezoelectric assemblies in FIGS. 1-7, FIG. 9 depicts an example of an electronic device 900 in which energy harvesting is enabled by way of a piezoelectric assembly 902. As shown in the embodiment depicted in FIG. 9, the electronic device 900 may include the piezoelectric assembly 902, a power converter 804, a bus bar 906, a power supply unit (PSU) 908, a controller 910, and electronic components 912. In various embodiments, the electronic device 900 may further include a fan tray and the piezoelectric assembly 902 may be disposed relative to a housing frame of the fan tray to harness vibrational energy produced by various operating fans in the fan tray.

In many embodiments, the piezoelectric assembly 902 may be coupled to the power converter 904. The power converter 904 may be configured to convert electrical signals generated by the piezoelectric assembly 902 into DC signals and then provide (e.g., dump) the DC signal into the bus bar 906. The bus bar 906 may be coupled to the PSU 908 and configured to power the electronic device 900. In a number of embodiments, the PSU 908 may include suitable logic, circuitry, and/or interfaces to provide power to electronic circuits, integrated circuits (ICs), or the like in the electronic device 900 or coupled to the electronic device 900. For example, the PSU 908 may receive power from the bus bar 906 and generate an output signal (e.g., a DC output voltage) that is used to power the controller 910, the electronic components 912, or the like.

In various embodiments, the controller 910 may include a suitable control logic, control circuitry, and/or interfaces to monitor load conditions of the PSU 908 and control the operation of the power converter 904 based on an enable signal 914. In one or more embodiments, the controller 910 may be coupled to the PSU 908 and may receive the output signal. A high load condition may be indicated if the output signal is greater than a first threshold value and a low load condition may be indicated if the output signal is less than a second threshold value. The second threshold value is less than the first threshold value.

In an example scenario, upon receiving the output signal from the PSU 908, the controller 910 may compare the output signal with the first threshold value and the second threshold value to determine whether the PSU 908 is experiencing a high load condition or a low load condition. In a case where the comparison indicates that the output signal is greater than the first threshold value, the controller 910 may assert (e.g., assert low or assert high) the enable signal 914 and provide the enable signal 914 to the power converter 904. Upon receiving the asserted enable signal 914, the power converter 904 may be enabled and may transform the electrical signal received from the piezoelectric assembly 902 into a DC signal. The bus bar 906 may serve as a central distribution point, delivering power to various connected electronic components 912 through the PSU 908. In other words, during high load conditions, the piezoelectric assembly 902 harvests electrical energy from fan vibrations, which the power converter 904 transforms into the DC signal and provides to the bus bar 906. Thus, ensuring the electronic components 912 receive a stable power supply even during peak loads. Once enabled, the controller 910 may not disable the power converter 904 until low load conditions are experienced.

However, in a case where the comparison indicates that the output signal is less than the second threshold value, the controller 910 may de-assert (e.g., de-assert low or de-assert high) the enable signal 914 and provide the enable signal 914 to the power converter 904. Upon receiving the de-asserted enable signal 914, the power converter 904 may be disabled and may not transform the electrical signal received from the piezoelectric assembly 902 into a DC signal. As a result, a supply of piezo-power to the bus bar 906 may be cut-off. Thus, to prevent overloading the bus bar 906 during low load conditions, dumping of piezo-power to the bus bar 906 is avoided by disabling the power converter 904 through the enable signal 914. This approach helps to maximize the efficiency of the PSU 908, minimize the risk of PSU damage, and prevent overvoltage conditions on the bus bar 906. Once disabled, the controller 910 may not enable the power converter 904 until the output signal becomes greater than the first threshold value. In certain scenarios, the first threshold value and the second threshold value may be sufficiently separated to prevent the enable signal 914 from glitching or chattering.

Although specific embodiments for example an electronic device 900 for energy harvesting and power supply are described above with respect to FIG. 9, any of a variety of systems and/or processes may be utilized in accordance with embodiments of the disclosure. For example, the power converter 904 may be connected to multiple piezoelectric assemblies through an adder circuit. The elements depicted in FIG. 9 may also be interchangeable with other elements of FIGS. 1-8 and FIGS. 10-13 as required to realize a particularly desired embodiment. More details about sustainability aware call routing are described below.

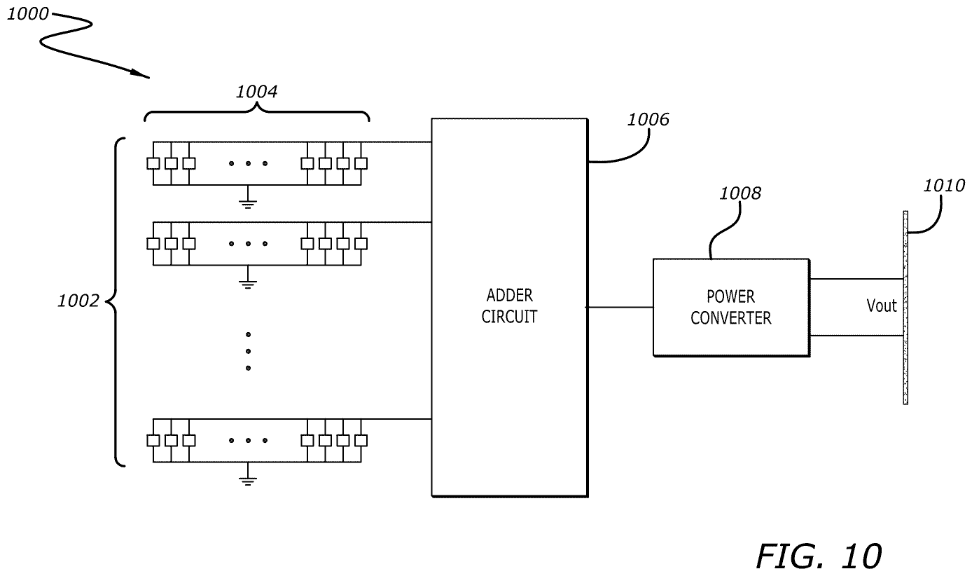

Referring to FIG. 10, a block diagram that illustrates supply of piezo-power from multiple piezoelectric assemblies included in a fan tray of an electronic device in accordance with various embodiments of the disclosure is shown. Having disclosed description of example piezoelectric assemblies in FIGS. 1-7, FIG. 10 depicts an example of an electronic device 1000 in which energy harvesting is enabled by way of a plurality of piezoelectric assemblies 1002. As shown in the embodiment depicted in FIG. 10, the electronic device 1000 may include the plurality of piezoelectric assemblies 1002. Each of the plurality of piezoelectric assemblies 1002 may include a set of piezoelectric transducer layers 1004, for example, a single piezoelectric transducer layer or multiple piezoelectric transducer layers. The electronic device 1000 may further include an adder circuit 1006, a power converter 1008, and a bus bar 1010. In various embodiments, the electronic device 900 may further include a fan tray and the plurality of piezoelectric assemblies 1002 may be disposed relative to a housing frame of the fan tray to harness vibrational energy produced by various operating fans in the fan tray and generate respective electrical signals.

In many embodiments, the plurality of piezoelectric assemblies 1002 may be connected in parallel to the adder circuit 1006. The adder circuit 1006 may include suitable logic, circuitry, and/or interfaces to receive the respective electrical signals from the plurality of piezoelectric assemblies 1002 and output a combined electrical signal. The combined electrical signal may be outputted based on an aggregation of the respective electrical signals. In other words, outputs from the plurality of piezoelectric assemblies 1002 may be fed to the adder circuit 1006 to sum or combine the electrical energy produced by the plurality of piezoelectric assemblies 1002. The adder circuit 1006 may be further coupled to the power converter 1008 and may provide the combined electrical signal to the power converter 1008. The power converter 1008 may include suitable logic, circuitry, and/or interfaces configured to convert the combined electrical signal to a DC signal and provide the DC signal to the bus bar 1010 for powering the electronic device 1000.

Although a specific embodiment for supplying piezo-power from multiple piezoelectric assemblies included in a fan tray of an electronic device for carrying out the various steps, processes, methods, and operations described herein is discussed with respect to FIG. 10, any of a variety of systems and/or processes may be utilized in accordance with embodiments of the disclosure. For example, the power converter 1008 may be a rectifier circuit that converts alternating current (AC) generated by multiple piezoelectric assemblies into DC signal. In further examples, the power converter 1008 can be an AC to DC converter. The elements depicted in FIG. 10 may also be interchangeable with other elements of FIGS. 1-9 and FIGS. 11-13 as required to realize a particularly desired embodiment.

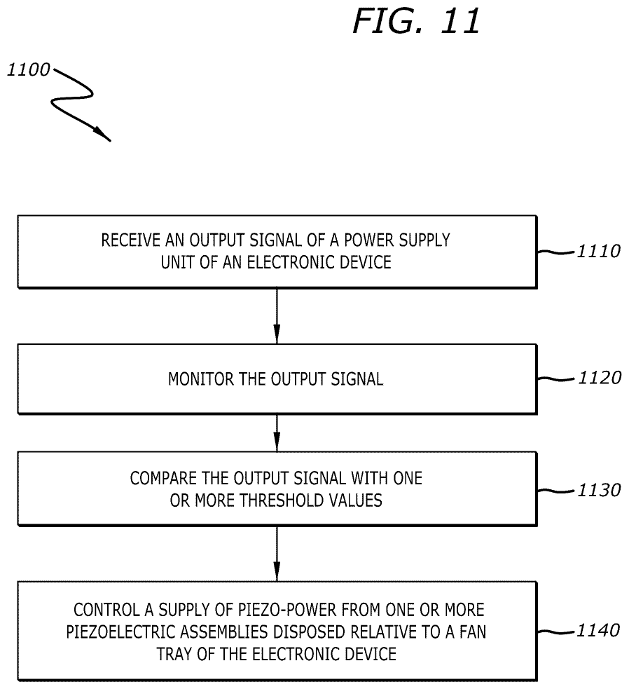

Referring to FIG. 11, a flowchart showing a process 1100 for controlling a supply of piezo-power generated by one or more piezoelectric assemblies included in a fan tray of an electronic device in accordance with various embodiments of the disclosure is shown. The process 1100 may be performed by a controller or a control logic of the electronic device. In many embodiments, the process 1100 may receive an output signal from a PSU of the electronic device (block 1110). The output signal may refer to a power level being delivered by the PSU, which may indicate whether the PSU is experiencing low load conditions or high load conditions.

In a variety of embodiments, the process 1100 may monitor the output signal (block 1120). The process 1100 may continuously monitor the output signal from the PSU to detect any deviations from expected values. The process 1100 may set one or more threshold values to indicate various load conditions experienced by the PSU. For example, the process 1100 may set a first threshold value which when exceeded by the output signal may indicate high load conditions. Further, the process 1100 may set a second threshold value such that if the output signal is less than the second threshold value, it may indicate low load conditions.

In a number of embodiments, the process 1100 may compare the output signal with the one or more threshold values (block 1130). For example, based on the monitoring, the process 1100 may compare the output signal with the first threshold value and the second threshold value. A comparison result may indicate whether the output signal is greater than the first threshold value, less than the second threshold value, or between the first threshold value and the second threshold value.

In several embodiments, the process 1100 may control the supply of piezo-power from one or more piezoelectric assemblies disposed relative to the fan tray (block 1140). The process 1100 may control the supply of piezo-power based on the comparison result. For example, in response to the comparison result indicating that the output signal is greater than the first threshold value, the process 1100 may enable a supply of the piezo-power. However, in response to the comparison result indicating that the output signal is less than the second threshold value, the process 1100 may cut-off the supply of the piezo-power. In many further embodiments, the process 1100 control the supply of piezo-power from the piezoelectric assemblies by enabling or disabling a power convertor coupled to the piezoelectric assemblies. For example, the power converter circuit may receive electrical signals from the piezoelectric assemblies, which are strategically positioned relative to a housing of the fan tray to harvest vibrational or mechanical energy generated by the fan's operation and convert into electrical signals (e.g., the piezo-power). In other words, the process 1100 may operate the power converter as a switch, which when disabled cuts off the supply of piezo-power and when enabled allows the piezo-power to be supplied to power various components of the electronic device.

Although a specific embodiment for controlling a power converter of an electronic device for harvesting energy suitable for carrying out the various steps, processes, methods, and operations described herein is discussed with respect to FIG. 10, any of a variety of systems and/or processes may be utilized in accordance with embodiments of the disclosure. For example, the one or more thresholds may include a single threshold value, which when exceeded may indicate high load condition, else a low load condition. The elements depicted in FIG. 11 may also be interchangeable with other elements of FIGS. 1-10 and FIGS. 12-13 as required to realize a particularly desired embodiment.

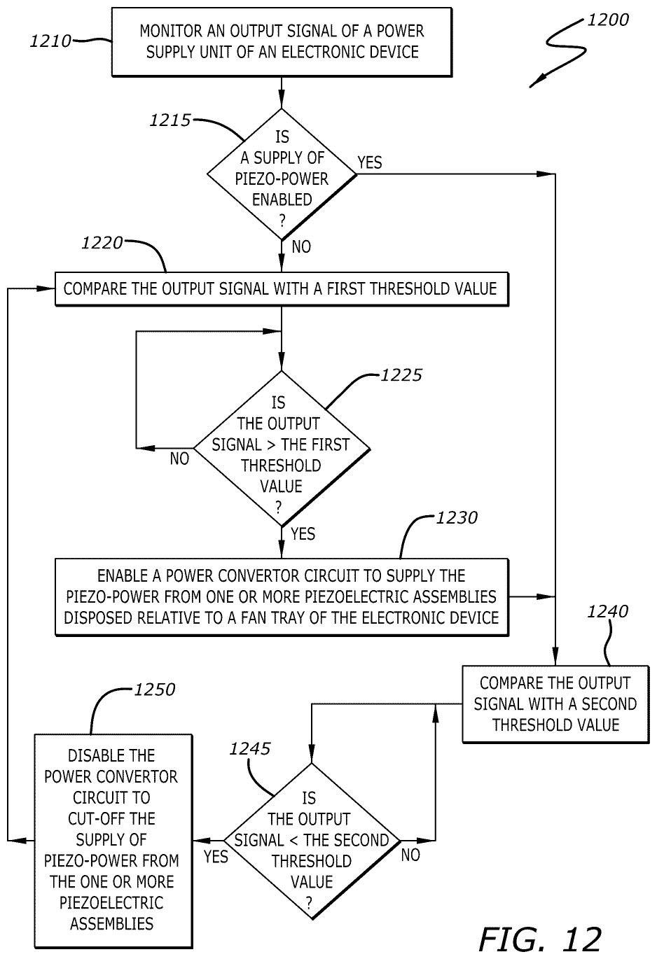

Referring to FIG. 12, a flowchart showing a process 1200 for controlling a supply of piezo-power generated by one or more piezoelectric assemblies included in a fan tray of an electronic device in accordance with various embodiments of the disclosure is shown. The process 1200 may be performed by a control logic in the electronic device. The control logic can be included a memory of the electronic device or may be embodied as a standalone component in the electronic device. In many embodiments, the process 1200 may monitor an output signal of a PSU of the electronic device (block 1210). The output signal may refer to a power level being delivered by the PSU, which may indicate whether the PSU is experiencing low load conditions or high load conditions.

In a number of embodiments, the process 1200 may determine if the supply of piezo-power is enabled (block 1215). That is to say, the process 1200 may determine if a power converter coupled to the piezoelectric assemblies, generating the piezo-power, is currently enabled or disabled. The power converter may be responsible for receiving electrical signals from the piezoelectric assemblies, transforming them into DC signals, and dumping piezo-power in the form of the DC signals into a bus bar coupled to the PSU.

In various embodiments, if the piezo-power is not enabled, the process 1200 may compare the output signal with a first threshold value (block 1220). The first threshold value may be utilized as an indicator of high load conditions. Thus, the first threshold value may serve as a reference to determine whether additional power from the piezoelectric assemblies is required to satisfy the high load conditions.

In additional embodiments, the process 1200 may determine whether the output signal is greater than the first threshold value (block 1225). If the output signal is below the first threshold value, the process 1200 may continue checking until the output signal rises above the first threshold value (block 1225). If the output signal exceeds the first threshold value, indicating high load conditions, the process 1200 may enable the power converter circuit to supply piezo-power from the one or more piezoelectric assemblies disposed relative to the fan tray of the electronic device (block 1230). In other words, the process 1200 may activate the power converter circuit to begin supplying electrical power generated by the piezoelectric assemblies various device components of the electronic device. For example, the power converter circuit may convert the electrical signals received from the piezoelectric assemblies into DC signal and provide it to a bus bar of the electronic device.

In further embodiments, the process 1200 may compare the output signal with a second threshold value (block 1240). Once the power converter circuit supplying the piezo-power is enabled, the process 1200 may compare the output signal with the second threshold value. The second threshold value may be utilized as an indicator of low load conditions. Thus, the second threshold value may serve as a reference to determine whether the PSU is dumped with excessive power. The second threshold value may be set to determine when the power converter circuit should be disabled to avoid overloading the electronic device or wasting energy when the primary power supply is sufficient.

In several embodiments, the process 1200 may determine whether the output signal is less than the second threshold value (block 1245). If the output signal is greater the second threshold value, the process 1200 may continue checking until the output signal falls below the second threshold value (block 1245). The output signal being greater than the second threshold value may indicate absence of low load conditions. Thus, if the output signal remains above the second threshold value, the power converter circuit continues to operate to maintain the supply of the piezo-power.

However, in one or more embodiments, if the output signal falls below the second threshold value, the process 1200 may disable the power converter circuit to cut-off piezo-power supply from the one or more piezoelectric assemblies (block 1250). For example, the process 1200 may provide a disable signal to the power converter circuit that may disable the power converter circuit, in turn cutting off the power converter circuit from the piezoelectric assemblies. This ensures that the piezo-power is supplied only when needed and does not overload the bus bar. The process 1200 may then loop back to compare the output signal with the first threshold value (block 1220).

Although a specific embodiment for enabling a power converter for power conversion suitable for carrying out the various steps, processes, methods, and operations described herein is discussed with respect to FIG. 12, any of a variety of systems and/or processes may be utilized in accordance with embodiments of the disclosure. For example, the process 1200 may send a single enable signal to the power converter circuit to enable or disable it. To activate the power converter circuit, the process 1200 may send an enable signal that is active high and to disable the power converter circuit, the process 1200 may make the enable signal active low. The elements depicted in FIG. 12 may also be interchangeable with other elements of FIGS. 1-11 and FIG. 13 as required to realize a particularly desired embodiment.

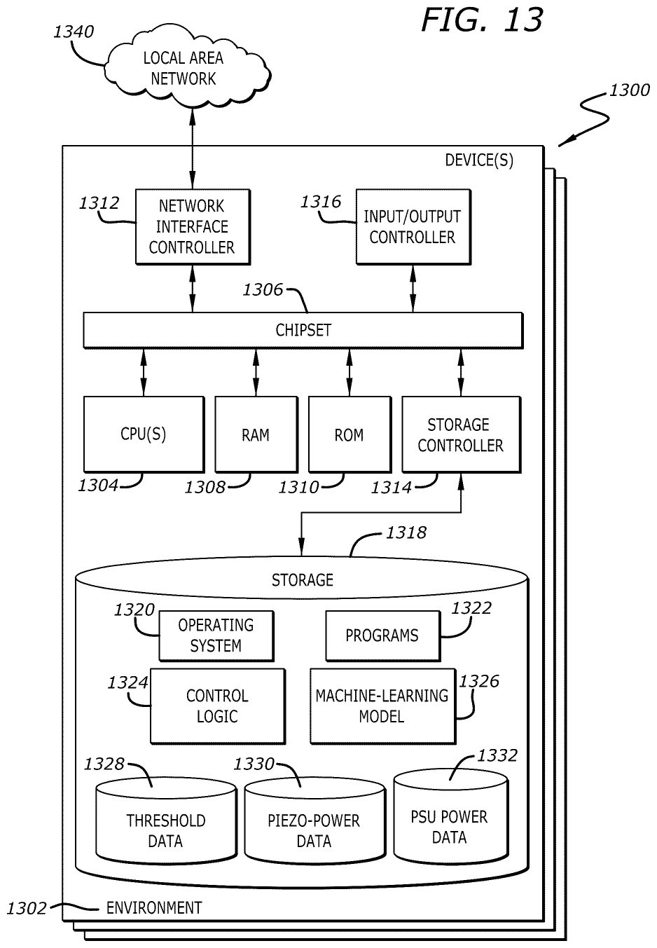

Referring to FIG. 13, a conceptual block diagram of a device 1300 suitable for configuration with a control logic, in accordance with various embodiments of the disclosure is shown. The embodiment of the conceptual block diagram depicted in FIG. 13 can illustrate a conventional server, computer, workstation, desktop computer, network appliance, or other computing device, and can be utilized to execute any of the application and/or logic components presented herein. The embodiment of the conceptual block diagram depicted in FIG. 13 can also illustrate an access point, a switch, or a router in accordance with various embodiments of the disclosure. The device 1300 may, in many nonlimiting examples, correspond to physical devices or to virtual resources described herein.

In many embodiments, the device 1300 may include an environment 1302 such as a baseboard or “motherboard,” in physical embodiments that can be configured as a printed circuit board with a multitude of components or devices connected by way of a system bus or other electrical communication paths. Conceptually, in virtualized embodiments, the environment 1302 may be a virtual environment that encompasses and executes the remaining components and resources of the device 1300. In more embodiments, one or more processors 1304, such as, but not limited to, central processing units (“CPUs”) can be configured to operate in conjunction with a chipset 1306. The processor(s) 1304 can be standard programmable CPUs that perform arithmetic and logical operations necessary for the operation of the device 1300.

In a number of embodiments, the processor(s) 1304 can perform one or more operations by transitioning from one discrete, physical state to the next through the manipulation of switching elements that differentiate between and change these states. Switching elements generally include electronic circuits that maintain one of two binary states, such as flip-flops, and electronic circuits that provide an output state based on the logical combination of the states of one or more other switching elements, such as logic gates. These basic switching elements can be combined to create more complex logic circuits, including registers, adders-subtractors, arithmetic logic units, floating-point units, and the like.

In various embodiments, the chipset 1306 may provide an interface between the processor(s) 1304 and the remainder of the components and devices within the environment 1302. The chipset 1306 can provide an interface to a random-access memory (“RAM”) 1308, which can be used as the main memory in the device 1300 in some embodiments. The chipset 1306 can further be configured to provide an interface to a computer-readable storage medium such as a read-only memory (“ROM”) 1314 or non-volatile RAM (“NVRAM”) for storing basic routines that can help with various tasks such as, but not limited to, starting up the device 1300 and/or transferring information between the various components and devices. The ROM 1310 or NVRAM can also store other application components necessary for the operation of the device 1300 in accordance with various embodiments described herein.

Additional embodiments of the device 1300 can be configured to operate in a networked environment using logical connections to remote computing devices and computer systems through a network, such as the network 1340. The chipset 1306 can include functionality for providing network connectivity through a network interface card (“NIC”) 1312, which may comprise a gigabit Ethernet adapter or similar component. The NIC 1312 can be capable of connecting the device 1300 to other devices over the network 1340. It is contemplated that multiple NICs 1312 may be present in the device 1300, connecting the device to other types of networks and remote systems.

In further embodiments, the device 1300 can be connected to a storage 1318 that provides non-volatile storage for data accessible by the device 1300. The storage 1318 can, for instance, store an operating system 1320, applications 1322, threshold data 1328, piezo-power data 1330, and PSU power data 1332 which are described in greater detail below. The storage 1318 can be connected to the environment 1302 through a storage controller 1314 connected to the chipset 1306. In certain embodiments, the storage 1318 can consist of one or more physical storage units. The storage controller 1314 can interface with the physical storage units through a serial attached SCSI (“SAS”) interface, a serial advanced technology attachment (“SATA”) interface, a fiber channel (“FC”) interface, or other type of interface for physically connecting and transferring data between computers and physical storage units.

The device 1300 can store data within the storage 1318 by transforming the physical state of the physical storage units to reflect the information being stored. The specific transformation of physical state can depend on various factors. Examples of such factors can include, but are not limited to, the technology used to implement the physical storage units, whether the storage 1318 is characterized as primary or secondary storage, and the like.

In many more embodiments, the device 1300 can store information within the storage 1318 by issuing instructions through the storage controller 1314 to alter the magnetic characteristics of a particular location within a magnetic disk drive unit, the reflective or refractive characteristics of a particular location in an optical storage unit, or the electrical characteristics of a particular capacitor, transistor, or other discrete component in a solid-state storage unit, or the like. Other transformations of physical media are possible without departing from the scope and spirit of the present description, with the foregoing examples provided only to facilitate this description. The device 1300 can further read or access information from the storage 1318 by detecting the physical states or characteristics of one or more particular locations within the physical storage units.

In addition to the storage 1318 described above, the device 1300 can have access to other computer-readable storage media to store and retrieve information, such as program modules, data structures, or other data. It should be appreciated by those skilled in the art that computer-readable storage media is any available media that provides for the non-transitory storage of data and that can be accessed by the device 1300. In some examples, the operations performed by a cloud computing network, and or any components included therein, may be supported by one or more devices similar to device 1300. Stated otherwise, some or all of the operations performed by the cloud computing network, and or any components included therein, may be performed by one or more devices 1300 operating in a cloud-based arrangement. By way of example, and not limitation, computer-readable storage media can include volatile and non-volatile, removable and non-removable media implemented in any method or technology.

By way of example, and not limitation, computer-readable storage media can include volatile and non-volatile, removable and non-removable media implemented in any method or technology. Computer-readable storage media includes, but is not limited to, RAM, ROM, erasable programmable ROM (“EPROM”), electrically-erasable programmable ROM (“EEPROM”), flash memory or other solid-state memory technology, compact disc ROM (“CD-ROM”), digital versatile disk (“DVD”), high definition DVD (“HD-DVD”), BLU-RAY, or other optical storage, magnetic cassettes, magnetic tape, magnetic disk storage or other magnetic storage devices, or any other medium that can be used to store the desired information in a non-transitory fashion.

As mentioned briefly above, the storage 1318 can store an operating system 1320 utilized to control the operation of the device 1300. According to one embodiment, the operating system comprises the LINUX operating system. According to another embodiment, the operating system comprises the WINDOWS® SERVER operating system from MICROSOFT Corporation of Redmond, Washington. According to further embodiments, the operating system can comprise the UNIX operating system or one of its variants. It should be appreciated that other operating systems can also be utilized. The storage 1318 can store other system or application programs and data utilized by the device 1300.

In many additional embodiments, the storage 1318 or other computer-readable storage media is encoded with computer-executable instructions which, when loaded into the device 1300, may transform it from a general-purpose computing system into a special-purpose computer capable of implementing the embodiments described herein. These computer executable instructions may be stored as application 1322 and transform the device 1300 by specifying how the processor(s) 1304 can transition between states, as described above. In some embodiments, the device 1300 has access to computer-readable storage media storing computer executable instructions which, when executed by the device 1300, perform the various processes described above with regard to FIGS. 1-13. In certain embodiments, the device 1300 can also include computer-readable storage media having instructions stored thereupon for performing any of the other computer-implemented operations described herein.

In still further embodiments, the device 1300 can also include one or more input/output controllers 1316 for receiving and processing input from a number of input devices, such as a keyboard, a mouse, a touchpad, a touch screen, an electronic stylus, or other type of input device. Similarly, an input/output controller 1316 can be configured to provide output to a display, such as a computer monitor, a flat panel display, a digital projector, a printer, or other type of output device. Those skilled in the art will recognize that the device 1300 might not include all of the components shown in FIG. 13 and can include other components that are not explicitly shown in FIG. 13 or might utilize an architecture completely different than that shown in FIG. 13.

As described above, the device 1300 may support a virtualization layer, such as one or more virtual resources executing on the device 1300. In some examples, the virtualization layer may be supported by a hypervisor that provides one or more virtual machines running on the device 1300 to perform functions described herein. The virtualization layer may generally support a virtual resource that performs at least a portion of the techniques described herein.

In many further embodiments, the device 1300 may include a control logic 1324. The control logic 1324 can be configured to perform one or more of the various steps, processes, operations, and/or other methods that are described above. Often, the control logic 1324 can be a set of instructions stored within a non-volatile memory that, when executed by the processor(s)/controller(s) 1304 can carry out these steps, etc. In numerous embodiments, the control logic 1324 may perform various operations related to controlling a power converter to in turn control a supply of piezo-power. In some embodiments, the device 1300 can be a electronic device including various fan trays to distribute cool air over electronic components and prevent overheating. The fan trays may further include piezoelectric assemblies to harness the vibrational energy produced by fans in the fan tray. The control logic 1324 may be configured to monitor an output signal of a PSU in the device 1300, compare the monitored output signal with one or more threshold values, and control, based on the comparison of the monitored output signal with the one or more threshold values, a supply of piezo-power from the piezoelectric assemblies.

In various embodiments, the storage 1318 can include the threshold data 1328. The threshold data 1328 may store the one or more threshold values utilized by the control logic 1324 to control the supply of the piezo-power from the piezoelectric assemblies. The one or more threshold values may include power levels required for enabling the supply of the piezo-power and/or disabling the supply of the piezo-power. The threshold data 1328 may include a lower threshold value that is set to indicate low load conditions of the device 1300. The control logic 1324 can disable the supply of the piezo-power if the main power supply (e.g., the output signal) drops below the lower threshold value. Further, the threshold data 1328 may include a higher threshold value that is set to indicate high load conditions of the device 1300. The control logic 1324 can enable the supply of the piezo-power if the main power supply (e.g., the output signal) exceeds below the higher threshold value.

In still more embodiments, the storage 1318 can include the piezo-power data 1330. The piezo-power data 1330 may refer to key measurements and characteristics associated with the electrical energy generated by the piezoelectric assemblies disposed in the device 1300, for example, relative to the fan tray housing of the device 1300. The piezo-power data 1330 may include voltage and current outputs, which indicate the electrical energy produced under specific loading conditions, as well as the overall power generation expressed in watts. Additionally, the piezo-power data 1330 covers the frequency response of the piezoelectric materials, detailing the range of frequencies at which effective energy conversion occurs. The piezo-power data 1330 may further include energy harvesting efficiency that reflects how well the piezoelectric assemblies convert mechanical energy into electrical energy. Lastly, the piezo-power data 1330 may include load conditions to assess how varying resistive or reactive loads impact the output performance, providing insights essential for optimizing piezoelectric systems in applications such as wearable electronics, sensors, and renewable energy solutions.

In a number of embodiments, the storage 1318 can include PSU power data 1332. The PSU power data 1332 may refer to measurements and characteristics that define the performance and output capabilities of the PSU. The PSU power data 1332 may include the output voltage, which must align with the operational requirements of connected devices, and the output current, indicating the maximum current the PSU can safely deliver. The power rating, expressed in watts, signifies the total output capacity of the PSU, while efficiency metrics reveal how effectively it converts input power to output, with higher efficiency indicating less energy loss. Additionally, load regulation measures the PSU's ability to maintain a stable output voltage despite fluctuations in load current, and ripple voltage assesses the unwanted fluctuations in output voltage, which can affect sensitive electronics.

Finally, in numerous additional embodiments, data may be processed into a format usable by a machine-learning model 1326 (e.g., feature vectors), and or other pre-processing techniques. The machine-learning (“ML”) model 1326 may be any type of ML model, such as supervised models, reinforcement models, and/or unsupervised models. The ML model 1326 may include one or more of linear regression models, logistic regression models, decision trees, Naïve Bayes models, neural networks, k-means cluster models, random forest models, and/or other types of ML models 1326.

Although a specific embodiment for a device suitable for configuration with a control logic for carrying out the various steps, processes, methods, and operations described herein is discussed with respect to FIG. 13, any of a variety of systems and/or processes may be utilized in accordance with embodiments of the disclosure. For example, the device may be in any data center servers that require cooling. The elements depicted in FIG. 13 may also be interchangeable with other elements of FIGS. 1-13 as required to realize a particularly desired embodiment.

Although the present disclosure has been described in certain specific aspects, many additional modifications and variations would be apparent to those skilled in the art. In particular, any of the various processes described above can be performed in alternative sequences and/or in parallel (on the same or on different computing devices) in order to achieve similar results in a manner that is more appropriate to the requirements of a specific application. It is therefore to be understood that the present disclosure can be practiced other than specifically described without departing from the scope and spirit of the present disclosure. Thus, embodiments of the present disclosure should be considered in all respects as illustrative and not restrictive. It will be evident to the person skilled in the art to freely combine several or all of the embodiments discussed here as deemed suitable for a specific application of the disclosure. Throughout this disclosure, terms like “advantageous”, “exemplary” or “example” indicate elements or dimensions which are particularly suitable (but not essential) to the disclosure or an embodiment thereof and may be modified wherever deemed suitable by the skilled person, except where expressly required. Accordingly, the scope of the disclosure should be determined not by the embodiments illustrated, but by the appended claims and their equivalents.

Any reference to an element being made in the singular is not intended to mean “one and only one” unless explicitly so stated, but rather “one or more.” All structural and functional equivalents to the elements of the above-described preferred embodiment and additional embodiments as regarded by those of ordinary skill in the art are hereby expressly incorporated by reference and are intended to be encompassed by the present claims.

Moreover, no requirement exists for a system or method to address each and every problem sought to be resolved by the present disclosure, for solutions to such problems to be encompassed by the present claims. Furthermore, no element, component, or method step in the present disclosure is intended to be dedicated to the public regardless of whether the element, component, or method step is explicitly recited in the claims. Various changes and modifications in form, material, workpiece, and fabrication material detail can be made, without departing from the spirit and scope of the present disclosure, as set forth in the appended claims, as might be apparent to those of ordinary skill in the art, are also encompassed by the present disclosure.

1. A fan tray, comprising:
a housing frame;
one or more fans housed in the housing frame and configured to generate a cooling airflow, wherein at least one fan of the one or more fans produces a vibration signal when in operation; and
one or more piezoelectric assemblies disposed relative to the housing frame, wherein the one or more piezoelectric assemblies are configured to convert the vibration signal into respective electrical signals.

2. The fan tray of claim 1, wherein a piezoelectric assembly of the one or more piezoelectric assemblies is disposed on an inner surface of the housing frame.

3. The fan tray of claim 2, wherein the piezoelectric assembly allows unobstructed airflow from the one or more fans.

4. The fan tray of claim 1, wherein a piezoelectric assembly of the one or more piezoelectric assemblies is disposed on an outer surface of the housing frame.

5. The fan tray of claim 1, wherein the vibration signal is produced as sound waves.

6. The fan tray of claim 1, wherein a piezoelectric assembly of the one or more piezoelectric assemblies comprises a set of piezoelectric transducer layers.

7. The fan tray of claim 6, wherein a piezoelectric transducer layer of the set of piezoelectric transducer layers comprises one or more piezoelectric elements that convert the vibration signal into an electrical signal of the respective electrical signals.

8. The fan tray of claim 7, wherein at least one piezoelectric element of the one or more piezoelectric elements is circular in shape.

9. The fan tray of claim 7, wherein at least one piezoelectric element of the one or more piezoelectric elements is rectangular in shape.

10. The fan tray of claim 7, wherein the piezoelectric transducer layer further comprises:
a dielectric sheet; and
a conducting material disposed on the dielectric sheet, wherein the one or more piezoelectric elements are disposed on the dielectric sheet and coupled to the conducting material.

11. The fan tray of claim 10, wherein the dielectric sheet comprises a dielectric material that has sound damping effect.

12. The fan tray of claim 10, wherein the conducting material is disposed on a peripheral area of the dielectric sheet.

13. The fan tray of claim 10, wherein the set of piezoelectric transducer layers comprises a stack of piezoelectric transducer layers with the one or more piezoelectric elements being sandwiched between the dielectric sheet and another dielectric sheet of an adjacent piezoelectric transducer layer in the stack of piezoelectric transducer layers.

14. The fan tray of claim 6, wherein the piezoelectric assembly further comprises at least two metal frames.

15. The fan tray of claim 14, wherein the set of piezoelectric transducer layers is sandwiched between the at least two metal frames.

16. The fan tray of claim 15, wherein the at least two metal frames are configured to resonate when subjected to the vibration signal.

17. An electronic device, comprising:
one or more electronic components; and
a fan tray comprising:
a housing frame;
one or more fans housed in the housing frame and configured to generate an airflow to cool the one or more electronic components, wherein at least one fan of the one or more fans produces a vibration signal when in operation; and
one or more piezoelectric assemblies disposed relative to the housing frame, wherein the one or more piezoelectric assemblies are configured to convert the vibration signal into respective electrical signals.

18. The electronic device of claim 17, further comprising:
a bus bar configured to power the electronic device;
an adder circuit coupled to the one or more piezoelectric assemblies and configured to:
receive the respective electrical signals; and
output a combined electrical signal based on the received respective electrical signals; and
a power convertor circuit configured to:
receive the combined electrical signal;
transform the combined electrical signal to a Direct Current (DC) signal; and
provide the DC signal to the bus bar.

19. The electronic device of the claim 18, further comprising:
a power supply unit coupled to the bus bar and configured to generate an output signal; and
a control logic configured to control enabling or disabling of the power convertor circuit based on the output signal, wherein the control logic:
enables the power convertor circuit in response to the output signal being greater than a first threshold value, or
disables the power convertor circuit in response to the output signal being below a second threshold value.

20. A method, comprising:
monitoring an output signal of a power supply unit in an electronic device;
comparing the monitored output signal with one or more threshold values; and
controlling, based on the comparison of the monitored output signal with the one or more threshold values, a supply of piezo-power from one or more piezoelectric assemblies disposed relative to a fan tray of the electronic device, the piezo-power being based on a vibration signal produced by at least one fan housed in the fan tray.
